(19) United States
(12) Patent Application Publication
(10) Pub. No.: US 2023/0266500 A1
(43) Pub. Date: Aug. 24, 2023

(54) GEOMECHANICS AND WELLBORE STABILITY MODELING USING DRILLING DYNAMICS DATA

(71) Applicant: Hamed Soroush, Brookhaven, GA (US)

(72) Inventor: Hamed Soroush, Brookhaven, GA (US)

(21) Appl. No.: 18/014,070

(22) PCT Filed: Jul. 30, 2021
(86) PCT No.: PCT/US21/43980

§ 371 Date: Dec. 30, 2022

Related U.S. Application Data
(60) Provisional application No. 63/059,260, filed on Jul. 31, 2020.

(51) Int. Cl. G01V 99/00; E21B 41/00; E21B 21/06; E21B 49/00; G06F 30/27

(52) U.S. Cl. CPC G01V 99/005; E21B 41/00; E21B 21/062; E21B 49/003; G06F 30/27; E21B 47/013

(57) ABSTRACT

In a method of generating a geomechanical model of a wellbore, at least one vibration sensor (422) is affixed to a drill bit unit (420). Electronic drilling recorder data (412) regarding drilling of the wellbore is received. Bit vibration data is received from the vibration sensor (422). A transform is applied to the electronic drilling recorder data and to the bit vibration data so as to generate filterable data. At least one undesirable component is filtered from the filterable data, thereby generating clean data. The clean data is applied to an artificial intelligence model trained to associate data with a plurality of geomechanical model components, thereby generating geomechanical model corresponding to the electronic drilling recorder data and the bit vibration data.

### CROSS-REFERENCE TO RELATED APPLICATION(S)

This application claims the benefit of U.S. Provisional Patent Application Ser. No. 63/059,260, filed Jul. 31, 2020, the entirety of which is hereby incorporated herein by reference.

### BACKGROUND OF THE INVENTION

### 1. Field of the Invention

The present invention relates to geomechanical modeling and, more specifically, to a system for generating a geomechanical model of a well based on electronic drilling recorder (EDR) data and bit vibration data.

### 2. Description of the Related Art

To ensure safe and cost-effective drilling operations, pre-drill and real-time determination of the rock properties, field stresses and pore pressure, and consequently the safe operating mud weight window is an added value. The common practice in the oil and gas industry is to develop pre-drill wellbore stability models including pore pressure gradient (PPG), collapse gradient (CG) and fracture gradient (FG). The prerequisite for a wellbore stability model is developing a one dimensional geomechanical model that includes continuous profiles for rock formations' mechanical properties, which can include: Young's Modulus, YM; Poisson's Ratio, PR; Uniaxial Compressive Strength, UCS; Friction Angle (FA), pore pressure (Pₚ), vertical stress (Sᵥ), minimum horizontal stress (Sₕₘᵢₙ) and maximum horizontal stress (S_{Hmax}).

To ensure safe and cost-effective subsurface operations, knowledge of the state of stress is essential. Specifically, in CO₂ sequestration operations, characterizing the in-situ stress state in the complex storage reservoirs and cap rocks is critical for safe storage of CO₂ and minimizing environmental hazards related to fluid leakage and induced seismicity.

Currently available methodologies for stress estimation tend to be heavily dependent on well logs such as density, sonic, porosity, etc. These inferences are based on simplified models or correlations which generally result in stress profiles with a large range of uncertainties. The required logs are usually not available in the overburden and also in horizontal wells where understanding the lateral changes in the state of stress and rock properties is very valuable for frac stage optimization. Also, seismic data that cover a larger volume of subsurface formations are lacking the vertical resolution required for subsurface stress characterization, especially for carbon storage purposes. These limitations identify an essential requirement for new sources of data for stress and rock properties evaluations, which provide higher resolution data with more substantial spatial coverage.

During drilling, a large volume of data is generated either on the rig or downhole by measurement while drilling (MWD) tools and other sensors installed in the bottom-hole assembly (BHA). However, due to a lack of robust interpretation schemes, these data have not been used to understand geomechanical characteristics of the formations, including rock properties and in-situ stresses. The exception is rudimentary mechanical specific energy (MSE) calculations; however, MSE analysis samples only part of the rich data set that is generated during drilling operations. The drill bit is the first BHA component meeting and logging a formation. With recent advancements in MWD, high-scanning-rate data can be collected near the bit. Since the bit-rock interface laws encapsulate information about all processes induced by the bit during drilling, the effects attributed to the bit, rock properties, and stresses should be differentiated through modeling.

Reliable estimation of these parameters results in accurate calculation of CG and FG for the wellbore stability model. However, establishing such a reliable geomechanical model is heavily dependent on high quality well logs such as gamma ray, resistivity, density, dipole sonic, porosity, etc. in both the reservoir and overburden intervals. Lack of such logs will impose large uncertainties to the developed geomechanical model and consequently the wellbore stability model. Furthermore, the available methodologies are based on simplified models or correlations which generally result in profiles with a large range of uncertainties and requirement to be calibrates against expensive field tests. The required logs are rarely available in the overburden sections, and also horizontal wells where understanding the lateral changes in rock properties, pore pressure and the state of stress is very important. Also, seismic data that cover a larger volume of subsurface formations are not of sufficient spatial resolution for drilling purposes.

These limitations and shortcomings identify an essential requirement for new sources of data for geomechanical modeling, which provide higher resolution data with more substantial spatial coverage.

An electronic drilling recorder (EDR) is a device that acquires data from various sources on an oil drilling rig. Such sources can include: mudlogging, lithology, pit volume totalizer (PVT), depth logging, etc. An EDR makes real-time surface parameters available for analysis. The EDR data can be used in making decisions regarding the operation of the drilling rig and in understanding the nature of the rock formations under the rig.

During drilling, a large volume of data is generated either on the rig or by downhole tools or sensors. However, due to a lack of robust interpretation schemes, these data have not been used to understand geomechanical characteristics of the formations. The exception is the use of rudimentary mechanical specific energy (MSE) for pore pressure estimation; however, MSE analysis samples only part of the rich data set that is generated during drilling operations. The drill-bit is the first BHA component meeting and logging a formation.

With the recent advancements in MWD, high-scanning-rate data can be collected near the bit, interpretation of these data, in combination with standard MSE procedures, enables creating profiles of rock properties, pore pressure and in-situ stresses. Previous experimental and analytical studies have provided invaluable information about the dynamic system response arising from the bit-rock interaction.

Therefore, there is a need for a system to determine geomechanical properties of formations using drilling dynamics data.

Therefore, there is a need for a system that generates depth-specific geomechanical models base on bit vibration data and EDR data.

There is also a need for a system for estimation of subsurface stresses without requirement for costly log data, using data that are readily available in all well intervals at no additional cost.

### SUMMARY OF THE INVENTION

The disadvantages of the prior art are overcome by the present invention which, in one aspect, is a method of generating a geomechanical model of a wellbore, in which at least one vibration sensor is affixed to a drill bit unit. Electronic drilling recorder data regarding drilling of the wellbore is received. Bit vibration data is received from the vibration sensor. A transform is applied to the electronic drilling recorder data and to the bit vibration data so as to generate filterable data. At least one undesirable component is filtered from the filterable data, thereby generating clean data. The clean data is applied to an artificial intelligence model trained to associate data with a plurality of geomechanical model components, thereby generating geomechanical model corresponding to the electronic drilling recorder data and the bit vibration data.

In another aspect, the invention is a method of drilling a well into strata, in which the strata is drilled into using a drill bit unit. Vibration data is received from a vibration sensor affixed to the drill bit unit. Electronic drilling recorder data regarding drilling of the wellbore is received. The electronic drilling recorder data includes drilling recorder data selected from a list consisting of: depth; weight-on-bit; torque-on-bit; rate of penetration; bit angular velocity; fluid pressure; and three-axis acceleration measured downhole near the bit at a high sampling rate. A geomechanical model of the strata at a specific bit location is calculated by executing the following steps: applying a transform to the electronic drilling recorder data and to the bit vibration data so as to generate filterable data; filtering at least one undesirable component from the filterable data, thereby generating clean data; and applying the clean data to an artificial intelligence model trained to associate data with a plurality of geomechanical model components, thereby generating the geomechanical model corresponding to the electronic drilling recorder data and the bit vibration data. Requirements for a mud weight window at the specific bit location are generated based on the geomechanical model. A mud meeting the requirements of the mud weight window is generated.

In yet another aspect, the invention is a drilling system in which a vibration sensor is affixed to a drill bit unit. A computer is responsive to the vibration sensor so as to receive bit vibration data from the vibration sensor. The is computer programmed to: receive electronic drilling recorder data regarding drilling of the wellbore; apply a function to transform a continuous-time signal into different scale components all assigned with a frequency range to the electronic drilling recorder data and to the bit vibration data so as to generate filterable data; filter at least one undesirable component from the filterable data, so as to generate clean data; and apply the clean data to a neural network trained to associate data with a plurality of geomechanical model components. The computer generates a geomechanical model corresponding to the electronic drilling recorder data and the bit vibration data.

These and other aspects of the invention will become apparent from the following description of the preferred embodiments taken in conjunction with the following drawings. As would be obvious to one skilled in the art, many variations and modifications of the invention may be effected without departing from the spirit and scope of the novel concepts of the disclosure.

### BRIEF DESCRIPTION OF THE FIGURES OF THE DRAWINGS

FIG. 1A is a block diagram showing one representative embodiment of a geomechanical model generating system during the training phase.

FIG. 1B is a block diagram showing one representative embodiment of a geomechanical model generating system during the determination phase.

FIG. 2 is a detailed block diagram showing one representative embodiment of a geomechanical model generating system.

FIG. 3A is a graphical illustration showing one example of sonic log denoising using a threshold criterion and optimum signal energy.

FIG. 3B is a graphical illustration showing one example of Signal decomposition in five levels using wavelet.

FIG. 3C is a graphical illustration showing original coefficients used in signal decomposition.

FIG. 3D is a graphical illustration showing thresholded coefficients used in signal decomposition.

FIG. 4 is a schematic diagram showing one embodiment of a geomechanical modeling system in use.

### DETAILED DESCRIPTION OF THE INVENTION

A preferred embodiment of the invention is now described in detail. Referring to the drawings, like numbers indicate like parts throughout the views. Unless otherwise specifically indicated in the disclosure that follows, the drawings are not necessarily drawn to scale. The present disclosure should in no way be limited to the exemplary implementations and techniques illustrated in the drawings and described below. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.”

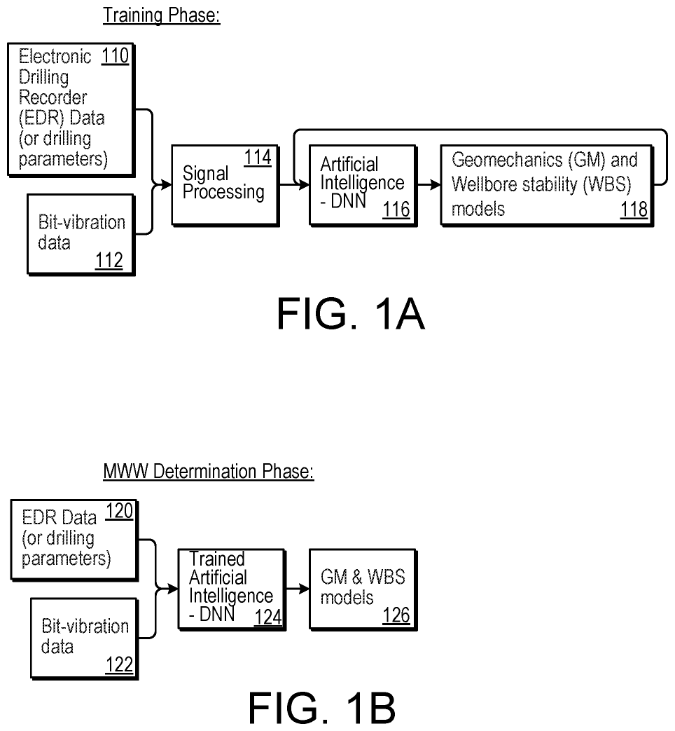

As shown in FIG. 1A, in one embodiment, wellbore depth-specific data, including electronic drilling recorder (EDR) data and other drilling parameters 110 and drill bit vibration data 112 (received from a vibration sensor that has been affixed to a drill bit unit) is fed into a signal processing unit 114 to render the depth-specific data filterable and to filter the filterable data so as to remove noise therefrom and thereby generate clean data. The electronic drilling recorder data can include, for example: depth; weight-on-bit; torque-on-bit; rate of penetration; bit angular velocity; fluid pressure; and three-axis acceleration measured downhole near the bit at a high sampling rate.

The clean data is fed into an artificial intelligence (AI) system 116 (such as a deep neural network) to train it to recognize geomechanical models geomechanics and wellbore stability models corresponding to the clean data. In the training process, the AI can generate output probabilities resulting in a model 118 having a highest probability of a match. This can be compared to known data regarding the actual model and neuron weights in the AI system can be adjusted to increase the accuracy of model prediction. Once the output of the AI system 116 converges on the correct model, the AI system is considered to be trained. The geomechanical model components can include, for example: pore pressure; in-situ stresses; collapse gradient; and fracture gradient.

As shown in FIG. 1B, the trained AI system 124 is used to generate a geomechanical model or a wellbore stability model, or both based EDR data and other drilling parameters 120 taken from the well and bit vibration data for the well 122. In certain embodiments, this data can be fed into the AI system 124 in real time or near real time. Based on these data, the AI system then generates geomechanical and wellbore stability models 126 that are specific to the current (or near current) position of the drill bit. In one embodiment, the models relate to the drill bit depth with half foot resolution.

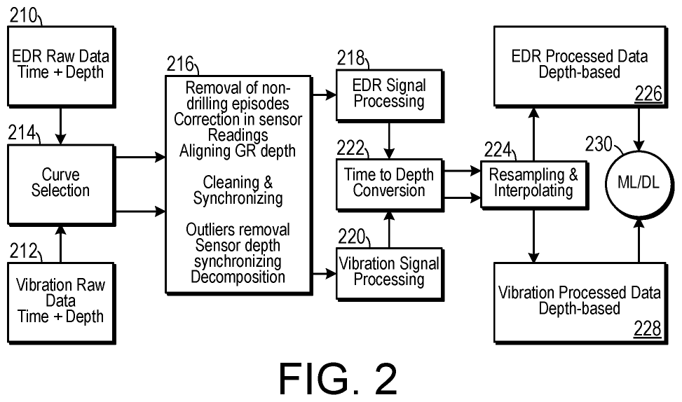

As shown in FIG. 2, a more detailed view of the AI training process, the EDR raw data 210 and the bit vibration data 212 include both time and bit depth information. A curve selection routine 214 conforms these data to a standard format. The resulting signals are then cleaned and synchronized 216 so as to remove data representing non-drilling episodes, to correct sensor readings and to align the data so as to correspond to sensed gamma ray (GR) depth. Also, at this stage outliers are removed, the data are synchronized and spectral decomposition of the measured bit acceleration is applied to the data. The EDR signal is then processed 218 and the vibration signal is also processed 220. Processing can include applying a transform to the data. The transform employs a function to transform a continuous-time signal into different scale components all assigned with a frequency range.

Both filtered signals are subjected to a time to depth conversion 222 with resampling to a half-foot resolution to match the resolution of the well logs used to estimate stresses 224. Well logs data used with the system can include: gamma ray data; sonic data; density data; resistivity data; and neutron porosity data; image data. The EDR depth-based data are processed by the AI system 226 and the vibration depth-based data are also processed by the IA system 228, resulting in the output of machine learning (ML)/deep learning (DL) models 230 corresponding to the desired depth-based geomechanical and wellbore stability models.

One embodiment employs offset data taken from an offset well. Such data can include: well logs; mud logs; daily drilling and geology reports; and end of well reports.

In one representative embodiment, downhole vibrations measured at the drill bit, near-bit or at any other location alongside the drill-string are records of a compound motion. This overall motion can be due to several causes, including dynamic dysfunctions, drilling process, rock properties, pore pressure and in-situ stresses. They are further influenced by factors such as drill-string design, drill bit design, operational parameters, and borehole conditions. Vibrations are time dependent and follow non-linear processes. Vibration measurements incorporate the effects of all these factors, with the addition of some process and measurement noises. Typically, vibration measurements are dominated by the effect of dysfunctions (e.g., low frequency torsional oscillations and stick-slip vibration). One representative embodiment extracts from such measurements data that are related to the in-situ stress state.

In the dataset used in this embodiment, downhole vibration data is measured by a set of accelerometers located in a dedicated sub inserted in the drill-string. Acceleration is measured in three mutually perpendicular directions (i.e., z axis along the direction of the drill-string and x and y axes in the plan perpendicular to it). The data are acquired downhole at a high sampling rate which allows investigation of a wide range of frequency content in the measured signal.

The system generates models directly relating downhole vibration measurements to in-situ stresses. The vibration data contains information related to the stress state and machine learning with properly conditioned input data is used to solve the problem. The system decomposes the measured downhole acceleration in several informative frequency bands; each banded component is fed independently into a machine learning model.

In addition to drilling vibrations, drilling data recorded at the surface (referred to as EDR or Electronic Drilling Recorder data) is used. The related equipment is typically installed on the rig to monitor, record and display drilling parameters and data real-time. Typical EDR data acquired at surface include drilling mechanics and drilling hydraulics parameters such as weight-on-bit (WOB), torque (TQ), angular velocity (RPM), axial rate of penetration (ROP), standpipe pressure (SPP), flow in (Total Pump Output or TPO) and differential pressure (DiffP or ΔP). In contrast with the vibration data, EDR data tends to be much lower resolution, with usual sampling rate of 1 second (i.e., 1 Hertz).

One dimensional (1D) geomechanical models, including a stress model, are used for targeted wells using the best industry exercise. Construction of the geomechanical model begins with rock mechanical property estimation using well logs calibrated to rock mechanics laboratory data. The important properties include Young's Modulus (YM), Poisson's Ratio (PR), Uniaxial Compressive Strength (UCS), Cohesive Strength (CS) and Friction Angle (FA). There are several empirical models to correlate these properties to the well logs; however, rock mechanics testing data are required to calibrate these models. These properties along with our best estimation of the pore pressure (Pp) are the main input to the stress model.

Stress modeling consists of creating a continuous vertical stress (Sᵥ) profile by integrating the product of density by depth:

$$( {z}_{0} ) = \int \begin{matrix}z 0 \\ ρ gdz \\ 0\end{matrix}$$

where z is depth, g is gravitational acceleration, and ρ is density.

It is followed by estimation of the minimum horizontal stress (Sh) using the “Pure Friction Failure” model, since it yields the best matching results with the drilling experiences and fracturing results:

Sₕ=(1, sin(FA))+Pₚ sin (FA)

The magnitude of the maximum horizontal stress (SH) is estimated using the Mohr-Coulomb failure criterion using the following equation and is calibrated to the wellbore failure evidence captured from image logs and drilling incidents reports. Effective stress ratio, stress polygon and analyzing wellbore breakouts and drilling induced tensile fractures were used to constrain SH magnitude:

$$1 + sin ( FA ) 2 CS cos ( FA )$$

$${S}_{H} = {S}_{h} + 1 , sin ( FA ) 1 , sin ( F A )$$

To validate the stress model, a wellbore stability study is performed to see if the overall geomechanical model can predict the problems experienced during drilling the well.

The system employs machine learning approaches to provide an explicit physical model relating downhole drilling dynamics data to in-situ stresses. It is believed that stress has a second order effect on drilling dynamics data with drilling system and rock properties having first order effects. Therefore, machine learning is an efficient tool to recognize the impact (and its related pattern) of each principal stress on the drilling dynamics data.

To overcome the lack of a complete data set in a single well, the system can combine the data from two neighboring wells (a vertical pilot well and a side-tracked deviated well) and use machine learning to bridge the gap in actual data. This can be achieved by augmenting the available data with synthetic data obtained using an auxiliary model. In this scenario, the first well has EDR data and well logs, but no vibrations data while the second well has EDR and vibration data, but no well logs.

With these two wells, the system can implement a multi-step approach in the modeling: first we use the first well to build an auxiliary model that generates synthetic well logs using EDR data and GR log as input. The auxiliary model is then applied to the second well to generate a set of synthetic well logs. The reason that this approach will work is the proximity and similarity of the wells (i.e., the same formations) and drilling system (i.e., the same tools and calibrations). These well logs can be used to calculate the stresses necessary to build the primary training dataset for the model relating input vibration and EDR data to output in-situ stresses.

In the overall workflow utilized for each of the two supervised machine learning (ML) models, the raw data, being vibration and EDR data, needs to be appropriately prepared and conditioned. This is the first necessary step leading to another type of preprocessing that is specific to machine learning and is detailed as follows: the initial preprocessing starts from a pool of different raw data from many wells. After a phase of data preparation (aggregation, collation, cleaning, time to depth conversion, resampling etc.), the data for each well is consolidated into a single data set ready for ingestion in the ML workflow. This dataset can be either raw measurements or modified dataset.

An experimental embodiment mostly ignores the dynamics of the signal and assumes that at each timestamp the dependent variable is explained by the independent features at that time only. Thus, to relate the input data in each row (representing the depth), to the output (three principal stress components), the embodiment applies regression methodologies that are designed for predicting multiple numeric values, referred to as multioutput regression models, such as linear, nonlinear regression and decision trees. There are also special workarounds that can be used to wrap and use those regression algorithms that do not natively support predicting multiple outputs.

In the most basic form, linear regression model explains a dependent variable y via a linear combination of the independent predictor signals xₕ, i.e.,

y=β0+β1x1+ . . . +⊖nxn+ϵ

where ϵ is an additive noise and is assumed to be white Gaussian noise. Despite its simplicity, this model can be used as a baseline and a tool to analytically study the independent variables and understand the significance of the input features.

To achieve more accurate estimates, however, the embodiment uses more sophisticated models such as regression trees. The number of splits and the depth of the decision trees are two important hyper parameters of these models which also controls the trade-off between model accuracy and generalization performance. Instead of using only one decision tree, the system can use an ensemble of multiple different models and fuse the individual predictions to make a final prediction. In general, ensemble learning can significantly outperform the typical single decision tree approaches. However, most of these techniques can suffer from the over-fitting problem. As such, in practice these ensemble learning techniques (e.g., gradient boosting, bootstrap aggregating) should be applied with special care and in scenarios where the size of the training data is very large compared to the feature size.

Decision trees tend to overfit on data with a large number of features. Getting the right ratio of samples to number of features is important, since a tree with few samples in high dimensional space is highly likely to overfit. To limit the number of features, one can perform dimensionality reduction (PCA, ICA, or Feature selection) beforehand to give the tree a better chance of finding features that are discriminative. In addition, there is a possibility that the selected features have multicollinearity relationship that must be removed before any training procedures.

Multicollinearity occurs when independent variables of regression model are strongly correlated. These correlations can cause problem, since independent variables should be truly independent. If the degree of correlation between variables is high enough, it can cause problems in training the model and interpreting the results. There are two basic kinds of multicollinearity:
Structural multicollinearity: This type occurs when a model term is created using other terms. In other words, it's a byproduct of the model that we specify rather than being present in the data itself. For example, if one squares term X to model curvature, clearly there is a correlation between X and X²; and
Data multicollinearity: This type of multicollinearity is present in the data itself rather than being an artifact of the model. Observational experiments are more likely to exhibit this kind of multicollinearity.

Multicollinearity affects the model coefficients and p-values, but it does not influence the predictions, precision of the predictions, and the goodness-of-fit statistics. If the primary goal is to make predictions, and there is no need to understand the role of each independent variable, then there is no need to reduce severe multicollinearity.

There is a simple test to assess multicollinearity in a regression model. The variance inflation factor (VIF) identifies correlation between independent input variables and the strength of that correlation. VIFs start at 1 and have no upper limit. A value of 1 indicates that there is no correlation between this independent variable and any others. VIFs between 1 and 5 suggest that there is a moderate correlation, but it is not severe enough to warrant corrective measures. VIFs greater than 5 represent critical levels of multicollinearity where the coefficients can be poorly estimated, and the p-values are questionable.

Random Forest is an ensemble learning technique which alleviates the over-fitting issue and usually offers excellent generalization performance. In this approach, multiple decision trees are constructed at training time and the mean (or the mode) of the individual predictions is reported as the output of the ensemble method. In this method, at each candidate splitting within each tree model, a randomly selected subset of feature space is used. This method has proven to be very effective and the resulting models are usually robust to the overfitting problem. Random forests have emerged as a versatile and highly accurate classification and regression methodology, requiring little tuning and providing interpretable outputs.

Random Forest regression refers to ensembles of regression trees where a set of n_tree un-pruned regression trees are generated based on bootstrap sampling from the original training data. For each node, the optimal feature for node splitting is selected from a random set of m_feature from the total N features. The selection of the feature for node splitting from a random set of features decreases the correlation between different trees and thus the average prediction of multiple regression trees is expected to have lower variance than individual regression trees. Larger m_feature can improve the predictive capability of individual trees but can also increase the correlation between trees and void any gains from averaging multiple predictions. The bootstrap resampling of the data for training each tree also increases the variation between the trees. The following hyperparameters need to be optimized for best learning and highest model accuracy when applied to blind datasets:

n_estimators: represents the total number of trees in the forest;
Max_depth: None means the nodes get expanded “until all leaves are pure or until all leaves contain less than “min_samples_split” samples. The higher the “max_depth,” the deeper the tree and the more splits that will be associated with that tree. More splits mean capturing more information. Therefore, a higher depth leads to over-fitting;
Min_sample_split: defined as “the minimum number of samples required to split an internal node.” High values of “min_sample_split” could lead to under-fitting because higher values of “min_sample_split” prevents a model from learning the details. In other words, the higher the “min_sample_split,” the more constraint the tree becomes since it has to consider more samples at each node;
Min_sample_leaf: is the minimum number of samples required to be at a leaf node.” An important difference between “min_sample_split” and “min_sample_leaf” is that the first focuses on an internal or decision node while the second focuses on a leaf or terminal node;
Max_feature: is defined as “The number of features to consider when looking for the best split”. For example, in classification problems, every time there is a split, the decision tree algorithm uses the defined number of features using gini or information gain. One of the main essences of using “max_feature” is to reduce overfitting by choosing a lower number of “max_features.” Max_feature can be set as the number of features;
Bootstrap: method for sampling data points (with or without replacement).

The most important settings are the number of trees in the forest (n_estimators) and the number of features considered for splitting at each leaf node (Max_features). These hyperparameters must be tuned for the best learning rate. The best method to find optimum hyperparameters for a multioutput regression RF model is using cross-validation.

Hyperparameter tuning relies more on experimental results than theory, and thus the best method to determine the optimal settings is to try many different combinations and evaluate the performance of each model. However, evaluating each model only on the training set can lead to overfitting. If the model is optimized for the training data, then the model will score very well on the training set but will not be able to generalize to new data, such as in a test set. When a model performs highly on the training set but poorly on the test set, this is known as overfitting, or essentially creating a model that knows the training set very well but cannot be applied to new problems. To avoid this issue, a multioutput regression using k-fold cross-validation is used.

The technique of cross-validation (CV) is best explained by example using the most common method, K-Fold CV. In any machine learning problem, the data is split into a training and a testing set. In K-Fold CV, the training set is further split into K number of subsets, called folds. The system then iteratively fit the model K times. Each time training is done on K−1 of the folds and evaluation is done on the K^{th} fold (called the validation set). As an example, consider fitting a model with K=5. The first iteration the system is trained on the first four folds and evaluate on the fifth. The second time the system is trained on the first, second, third, and fifth fold and evaluated on the fourth. The system repeats this procedure three more times, each time evaluating on a different fold. At the very end of training, the system averages the performance on each of the folds to come up with final validation metrics for the model.

For hyperparameter tuning, the system performs many iterations of the entire K-Fold CV process, each time using different model settings. The system then compares all of the models, selects the best one with the highest accuracy metrics, trains it on the full training set, and then evaluates on the testing set. This process is computationally tedious. Each time one attempts to assess a different set of hyperparameters, one has to split the training data into K fold and train and evaluate K times. If there are 10 sets of hyperparameters and the system uses 5-Fold CV, that represents 50 training loops. To cover a wider range of hyperparameter, one may use a random approach to pick each hyperparameter in a range, and then apply the k-Fold CV method. The benefit of a random search is that the system is not trying every combination and that can save time in training on very large datasets. Machine learning is a field of trade-offs, and performance versus time is one of the most fundamental. Applying k-fold CV generates the mean and standard deviation of mean absolute error (MAE) and root mean squared error (RMSE) across all folds and all repeats, which can be used to show how the model's training evolves. All these processes can be performed using the RandomizedSearchCV library in scikit-learn open-source software.

The initial part of this disclosure focuses on the collection and collation of appropriate datasets containing both downhole drilling dynamics data measured at high sampling frequency and well logs.

In one experimental embodiment, some datasets were depth-based records (logs, and surveys), others are time-based records (EDR and vibration). Time-based records included both timestamps and corresponding depth, which can be used to render the conversion from time-based to depth-based data.

In the experimental embodiment, most of the data preparation and conditioning was performed using Matlab. To handle the use of the large files with data analysis scripts that can run in reasonable amount of time, a three-step data conversion method was utilized. The first step, the initial ingestion, was the most time-consuming step as the large ascii files were to be read into Matlab. Once the data set is loaded in Matlab, the second step was to save the data into a mat file (binary Matlab files, smaller and faster to open than the csv files). Steps 1 and 2 were intended to be executed only once. The third step was to open the desired mat file to retrieve the data every time it is needed for analysis.

The goal of the data preprocessing is to build a set of labeled (supervised) data that can be fed into the machine learning model directly with minimum requirement for adjustments. The result of the process is a depth-based file that contains all the labeled curves necessary for the inputs and outputs of the machine learning models.

Because depth-based stress data is used to construct the models, all data sets should be conditioned as depth-based records. The maximum depth resolution that was used for the model in the experimental embodiment was limited to 0.5 ft., which was the depth resolution of the log data. In this embodiment, all the data were ultimately conditioned as half-foot records for ingestion in the model.

Usually, various amounts of data cleaning are required, depending on the quality of the EDR data. Typically, the EDR records include both timestamps and depth, and the processing is performed as follows:

Data cleaning: the time-based data is examined to identify and correct any issue such as sensor calibration and zeroing (e.g., WOB data) or anomalies in the depth record.

Extraction of drilling data only: the time histories record the data continuously, whether the hole is being drilled (active drilling ahead) or not. Non-drilling episodes include connection time, periods of standstill, pulling the drill-string in or out of the hole, etc. They can make up for a significant amount of the total time-based data recorded. It is important to properly identify intervals of active drilling and isolate them from the rest of the data. Drilling flags are determined using a rule-based automated approach first, and then are QC'ed and adjusted by visual inspection of the data.

Time-based data to depth-based data conversion: active drilling ahead implies hole creation with increasing depth (MD) without depth reversals or multiple data at a given depth. Time-based drilling data is therefore parsed accordingly using an automated scheme, resulting in a non-uniformly sampled depth-based data set.

Creation of the half-foot data set: the last step is to resample and interpolate the depth-based data to generate a data set with half-foot sampling that is properly aligned every half-foot.

In the experimental embodiment, initial processing of the vibration data (accelerations ax, ay and az) included:
Synchronizing the timestamps with those in the EDR data, to allow for the comparison of the time histories of both data sets.
Aligning the depth of the vibration data with the bit depth (the depth offset correction is based on the information in the Bottom-hole assembly report).
Eliminating the non-drilling portions of the data and converting the time-based data to depth-based data.
Resampling and interpolating the depth-based data to obtain a uniformly sampled half-foot data set that is correctly aligned on a half-foot grid.

The result is a depth-based compound vibration data; it includes the effects of drilling dynamics and rock cutting among others, acting as de-facto noise overshadowing the effects of in-situ stresses. Additional processing may be necessary to obtain vibration data that are good enough for the modeling. The data should be decomposed according to its spectral content. The goal is to extract frequency bands from the original vibration data to isolate areas in the frequency spectrum that potentially contain improved levels of signal to noise for the problem at hand, i.e., the response to the in-situ stresses. The workflow used in the experimental embodiment is as follows:
The process starts with the synchronized and depth aligned time-based data from the initial processing phase, before conversion to depth.
Frequency decomposition:
   With an actual highest frequency of 200 Hz, the maximum usable frequency range is only 0-100 Hz. It is indeed well-known in signal processing that the useful spectrum is limited to the so-called Nyquist frequency or folding frequency, 100 Hz in this case.
   The spectral content is examined.
   A total of six bands were chosen in the experimental embodiment to test the concept: 0-1 Hz, 1-5 Hz, 5-15 Hz, 15-25 Hz, 25-50 Hz and 50-90 Hz. The choice of the cut-off frequencies for the bands is based on reviewing the spectrograms of ax and ay. Little activity was noted in the 90-100 Hz band and, this band was ignored. The 0-1 Hz band is typically associated with low-frequency torsional vibration for ax and ay. While it is recognized that these vibrations are predominant in the acceleration data and may mask any other effects, the 0-1 Hz band may also be included in the analysis for all three accelerometer data sets.
   The Matlab built-in function bandpass was used to decompose the data into the five frequency bands higher than 1 Hz. It implements a band-pass filter designed as a minimum-order filter with a stopband attenuation of 60 dB and compensates for the delay introduced by the filter.
   The Matlab built-in function lowpass was used to extract the 0-1 Hz band data. It also implements a band-pass filter designed as a minimum-order filter with a stopband attenuation of 60 dB and compensates for the delay introduced by the filter.
Each data set is then separately converted from time to depth before being resample

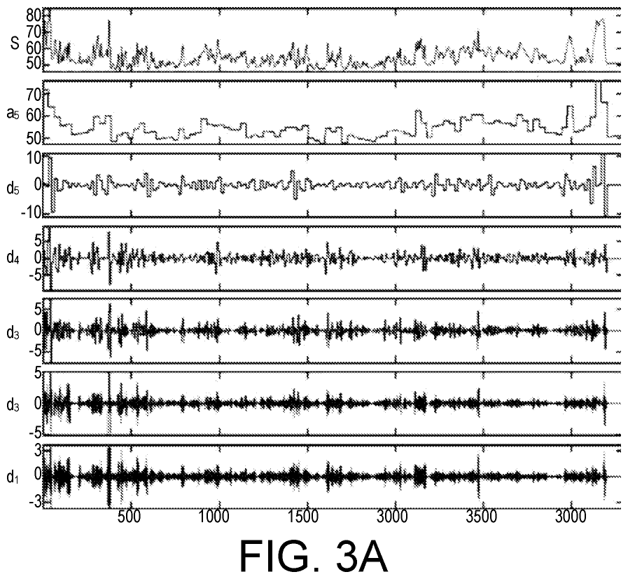

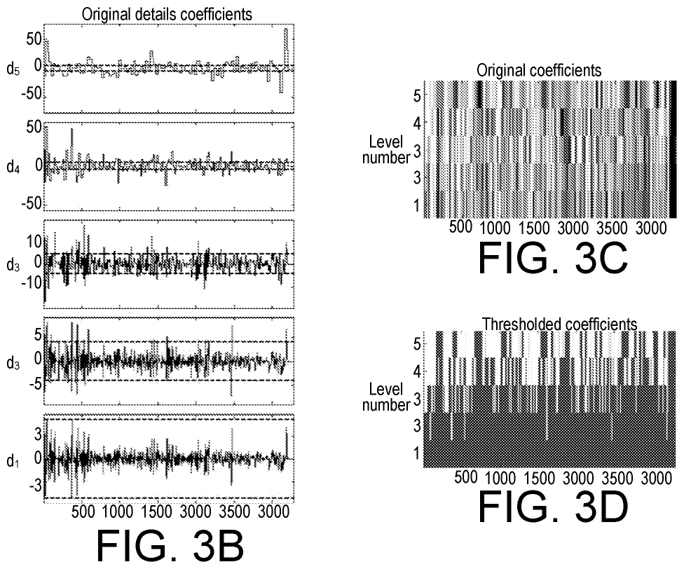

One example of a graphical illustration of sonic log denoising using a threshold criterion and optimum signal energy is shown in FIG. 3A. A graphical illustration signal decomposition in five levels using wavelet is shown in FIG. 3B. A graphical illustration of original coefficients used in signal decomposition is shown in FIG. 3C. A graphical illustration of thresholded coefficients used in signal decomposition is shown in FIG. 3D.

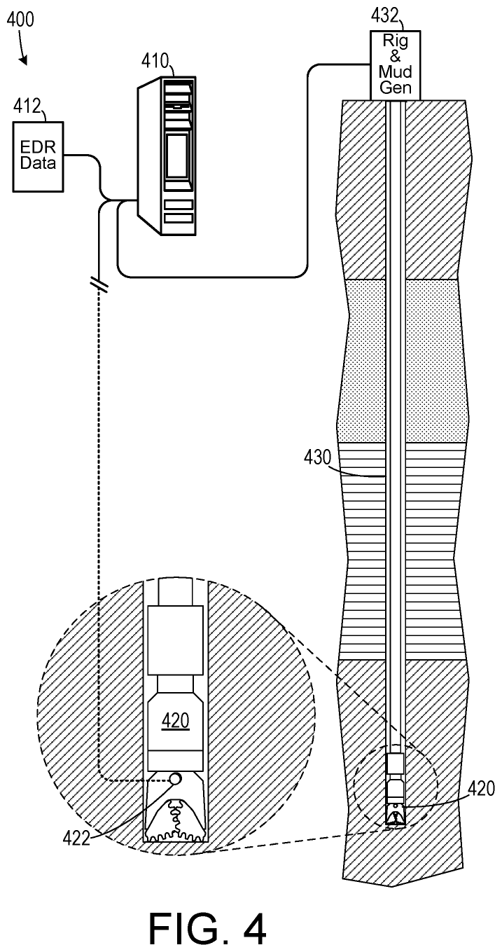

As shown in FIG. 4, one example of a practical embodiment of a drilling system 400 includes a computer 410 that receives EDR data 412 and vibration data from a vibration transducer 422 that has been affixed to a drill bit unit 420. The computer 410 is programmed to run the AI system to generate geomechanical and wellbore stability models and to generate useful information based there, such as a mud weight window. In a real time embodiment, the computer can supply control information to a SCADA system associated with a drilling rig 432 to generate mud formulations that comply with a calculated mud weight window as the wellbore 430 is being drilled. In a practical application, the model can be used to generate requirements for a mud weight window at the specific bit location based on the geomechanical model. A mud meeting the requirements of the mud weight window can then be generated

A methodology used to conduct post-mortem and real-time wellbore stability analysis based on drilling dynamics data. The subject drilling data can include:
Depth,
Weight-on-bit,
Torque-on-bit,
ROP
Bit angular velocity,
Fluid pressure, and
Three-axis acceleration measured downhole near the bit at a high sampling rate.

To train and calibrate the algorithms, the following data can be received from offset wells:
Well logs (GR, DTC, DTS, RHOB, Res, Image),
Mud logs,
Daily drilling and geology reports, and
End of well reports.

Parameters that are extracted by the analysis can include:
Pore pressure,
In-situ stresses (Sᵥ, Sₕₘᵢₙ, and S_{Hmin}),
Collapse gradient (CG), and
Fracture gradient (initiation, FGᵢ; propagation, FGₚ; and reopening, FGᵣₑ

The methodology combines the developed knowledge related to bit-rock interaction with signal processing and artificial intelligence to estimate geomechanical properties from drilling dynamics data measured downhole and acquired at a high sampling rate. In one embodiment, the system includes a software package that uses drilling dynamics data to produce profiles of rock properties, pore pressure and principal stresses along the borehole in real-time and post-drill. It provides 1-D geomechanical and wellbore stability models along vertical, deviated, or horizontal wells.

The wellbore stability model provides a safe operating mud weight window for drilling operation and help optimizing the mud design (pressure and composition) and casing design. A reliable safe operating mud weight window is required for safe and economic drilling of any wells. It helps significantly to identify and mitigate drilling hazards, minimize non-productive time (NPT) and reduce the cost of drilling. The methodology provides safe operating mud weigh window without requirement of wireline logging or LWD, by using only drilling dynamics data which are typically available. The benefits of the system may include:
Providing PPG, CG and FG from surface/mudline all the way to the bottom of the well,
Saving significant time and money on logging (specifically for the overburden where no petrophysical analysis needed),
Providing real-time opportunity for risk identification and mitigation (increases safety in rig-site),
Minimizing non-productive time (NPT) related to influx, lost circulation, and formation collapse, and
establishing calibrated geomechanical model for any prospective operations (completions, stimulation, reservoir modeling, production etc.

The workflow of the system combines analytical methods with advanced signal processing and machine learning algorithms. Two main approaches are employed to estimate the target parameters from the vibration data. A traditional regression analysis is used to better understand the data and to perform the preprocessing steps such as denoising, outlier detection and model selection tasks. This approach is likely to be reliable for stationary data and may not, in its basic form, account for the dynamics of a time series data. The problem can be viewed as a supervised learning task.

Applying a regression analysis to estimate a dependent variable from a time series data may result in poor model fitting and generalization. Various analysis and techniques can be employed to pre-process each feature of input space in order to remove the noise and unwanted outliers. After normalizing each feature to a standard form, the system can employ wavelet analysis to detect and remove the noise cause by sensor issues or background vibrations in the environment. This analysis can also be used to decompose the signal into more informative frequency bounds which can be added to the model as supplementary derivative features as well. One embodiment employs optimally designed Wavelet denoising system as part of the system. In addition to the denoising, the system can consider the effects of temporal correlation between consecutive readings of each feature. While individual features may be non-stationary, the regression model assumes the residual signal to be stationery and deviance from this assumption invalidates the model and subsequent analysis. Further, in time series analysis, a similar trend between an independent and the dependent variable can result in an invalid analysis. Spurious regression is one such case that two completely unrelated series with the same trend may cause an inflated significance testing result. Removing the temporal correlation can be a remedy in such cases. A simple first order difference or more sophisticated predicators such as Recursive Least Square (RLS) filtering to remove the temporal correlation may be considered.

Based on the available data from several offset wells, high depth resolution 1D geomechanical models, including rock properties, pore pressure and in-situ stresses can be developed based on log-based classical analytical methods. These models can be used as benchmark to train the algorithms and optimized them to the specific type of formations presents in the study fields.

Feature selection is one of the core concepts of machine learning that hugely impacts the performance of the model. This process consists of two main steps: (1) Adding new features derived from the raw data; and (2) Removing the undesired features from the final selection.

In the first step, the system extracts more relevant features from the raw data. For a typical numerical data that belongs to a time series, this may include the current mean and variance of the input feature as wells as frequency information. In this regard, the data can be augmented with Short Time Fourier Transform (STFT) to add relevant frequency information to the time series data. Learning from the meticulously augmented feature vectors can be much faster and does not require complex learning models. The next step is to select a subset of important features. There are three main criteria that are considered: (1) feature significance; (2) avoiding collinearity; and (3) model selection penalties.

Regression models are some of the most fundamental techniques in machine learning. In the most basic form, linear regression model explains a dependent variable y via a linear combination of the independent predictor signals xᵢ, for example:

y=β0+β1x1+ . . . +βnxn+ϵ

where ϵ is an additive noise and is assumed to be a white Gaussian noise. Despite its simplicity, this model is widely used as a baseline and as a tool for analytical study of the independent variables and to understand the significance of the input features. The following disclosure addresses some of the main aspects of the data processing as part of the regression model analysis.

Linear regression analysis is used to study the feature space and for the model selection. Despite its simplicity and the linearity assumption, this model usually performs reasonably well and has good generalization performance. The system can also employ more sophisticated models, such as regression trees to achieve more accurate estimates. Basic linear regression is a method that assumes one single linear formula for the whole space of features. However, most of the relations between features are not perfectly linear. Further, finding a generalized nonlinear relation for large space of features may not be practical and can be employed only under certain strong assumptions.

One alternative is to sub-divide (partition) the space into smaller regions where the interactions are more manageable. These regions can be recursively divided until the smallest of regions can be faithfully explained by a linear model. The dividing forms a tree where we start from the root and divide each node by asking a question similar to “is feature xᵢ greater than 1.5?” There are various algorithms based on this core idea of recursive splitting of feature space. One of the ways different decision tree algorithms differ is the way this splitting is carried out. The mostly adopted criteria for splitting are the Gini Index and the Information gain. The number of splits and the depth of the decision trees are two important hyper parameters of these models which also controls the tradeoff between model accuracy and generalization performance.

Instead of using only one decision tree, the system can use an ensemble of multiple different models. The final prediction then can be carried out by the averaging the prediction of the individual models. In general, ensemble learning can significantly outperform the typical single decision tree approaches. However, most of these techniques can suffer from the over-fitting problem. As such, in practice these ensemble learning techniques (e.g., gradient boosting, bootstrap aggregating) should be applied with special care and in scenarios where the size of the training data is very large compared to the feature size. Random Forest is an ensemble learning technique which alleviates the over-fitting issue and usually offers excellent generalization performance. In this approach multiple decision trees are constructed at training time and the mean (or the mode) of the individual predictions is reported as the output of the ensemble method. In this method, at each candidate splitting within each tree model, a randomly selected subset of feature space is used. This has proven to be effective and the resulting models are usually robust to the over-fitting problem.

An initial analysis mostly ignores the dynamics of the signal and assumed that at each timestamp the dependent variable is explained by the independent features at that time. However, before further analysis, it may not be clear if this simplifying assumption is valid. While there are traditional statistical approaches for learning the dynamics of the model and incorporating past sequences in the time-series forecasting (e.g., Auto Regressive Moving Average-ARMA, Seasonal ARMA, etc.) these models are usually mathematically complex and may work only under certain conditions. Recurrent Neural Networks (RNNs) have shown to outperform the standard statistical approaches in variety of the time series analysis including speech recognition. At a very high level, an RNN cell provides a neural mechanism for learning autoregressive models with an impressive flexibility. There are variety of designs for these recurrent cells, for example Vanilla RNN, Long Short-Term Memory (LSTM) and multidimensional RNNs. LSTM cells are very efficient and can learn long correspondences due to their gated design.

Despite their superior performance compared to the traditional statistical approach, they have some shortcomings. For example, unlike the linear regression, it may not be easy to estimate the confidence level for RNN predictions or to estimate the significance of each feature analytically. One way to address this is to employ the ensemble learning paradigm. Several different RNN models may be employed and voting (e.g, averaging) may be performed. One way to design multiple models is to use different training data for each model. It is also possible to use an approach similar to the Random Forest and to select subsets of the features randomly in each model and then use the aggregate model for the prediction. In addition to the confidence testing, this can also alleviate the over-fitting problem which is usually the weak point of neural approaches. In time series analysis and especially when the sample rate is high enough, it can be beneficial to incorporate the frequency information in the time series forecasting as well. Frequency information can be added as part of the input features. RNNs on the other hand, allow the incorporation of this side information more systematically. This can be accomplished using a 2D grid LSTM which process the data sequentially in two directions of time and frequency. This Time-Frequency LSTM (TF-LSTM) can make it possible to incorporate the frequency information into the prediction model.

Although specific advantages have been enumerated above, various embodiments may include some, none, or all of the enumerated advantages. Other technical advantages may become readily apparent to one of ordinary skill in the art after review of the following figures and description. It is understood that, although exemplary embodiments are illustrated in the figures and described below, the principles of the present disclosure may be implemented using any number of techniques, whether currently known or not. Modifications, additions, or omissions may be made to the systems, apparatuses, and methods described herein without departing from the scope of the invention. The components of the systems and apparatuses may be integrated or separated. The operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set. It is intended that the claims and claim elements recited below do not invoke 35 U.S.C. § 112(f) unless the words “means for” or “step for” are explicitly used in the particular claim. The above-described embodiments, while including the preferred embodiment and the best mode of the invention known to the inventor at the time of filing, are given as illustrative examples only. It will be readily appreciated that many deviations may be made from the specific embodiments disclosed in this specification without departing from the spirit and scope of the invention. Accordingly, the scope of the invention is to be determined by the claims below rather than being limited to the specifically described embodiments above.

What is claimed is:

1. A method of generating a geomechanical model of a wellbore, comprising the steps of:
(a) affixing at least one vibration sensor to a drill bit unit;
(b) receiving electronic drilling recorder data regarding drilling of the wellbore;
(c) receiving bit vibration data from the vibration sensor;
(d) applying a transform to the electronic drilling recorder data and to the bit vibration data so as to generate filterable data;
(e) filtering at least one undesirable component from the filterable data, thereby generating clean data; and
(f) applying the clean data to an artificial intelligence model trained to associate data with a plurality of geomechanical model components, thereby generating geomechanical model corresponding to the electronic drilling recorder data and the bit vibration data.

2. The method of generating a geomechanical model of a wellbore of claim 1, wherein the transform comprises a function to transform a continuous-time signal into different scale components all assigned with a frequency range.

3. The method of generating a geomechanical model of a wellbore of claim 1, wherein the artificial intelligence model comprises a deep neural network.

4. The method of generating a geomechanical model of a wellbore of claim 1, wherein the electronic drilling recorder data includes drilling recorder data selected from a list consisting of: depth; weight-on-bit; torque-on-bit; rate of penetration; bit angular velocity; fluid pressure; three-axis acceleration measured downhole near the bit at a high sampling rate; and combinations thereof.

5. The method of generating a geomechanical model of a wellbore of claim 1, further comprising the steps of:
(a) receiving offset data from at least one offset well; and
(b) applying the offset data to the neural network.

6. The method of generating a geomechanical model of a wellbore of claim 5, wherein the offset data includes offset data selected from a list consisting of: well logs; mud logs; daily drilling and geology reports; end of well reports; and combinations thereof.

7. the method of generating a geomechanical model of a wellbore of claim 5, wherein the well logs data include well logs data selected from a list consisting of: gamma ray data; sonic data; density data; resistivity data; neutron porosity data; image data; and combinations thereof.

8. The method of generating a geomechanical model of a wellbore of claim 1, wherein the geomechanical model components include geomechanical model components selected from a list consisting of:
pore pressure; in-situ stresses; collapse gradient; fracture gradient and combinations thereof.

9. A method of drilling a well into strata, comprising the steps of:
(a) drilling into the strata using a drill bit unit;
(b) receiving vibration data from a vibration sensor affixed to the drill bit unit;
(c) receiving electronic drilling recorder data regarding drilling of the wellbore, wherein the electronic drilling recorder data includes drilling recorder data selected from a list consisting of: depth; weight-on-bit; torque-on-bit; rate of penetration; bit angular velocity; fluid pressure; three-axis acceleration measured downhole near the bit at a high sampling rate; and combinations thereof;
(d) calculating a geomechanical model of the strata at a specific bit location by executing the following steps:
(i) applying a transform to the electronic drilling recorder data and to the bit vibration data so as to generate filterable data;
(ii) filtering at least one undesirable component from the filterable data, thereby generating clean data; and
(iii) applying the clean data to an artificial intelligence model trained to associate data with a plurality of geomechanical model components, thereby generating the geomechanical model corresponding to the electronic drilling recorder data and the bit vibration data;
(e) generating requirements for a mud weight window at the specific bit location based on the geomechanical model; and
(f) generating a mud meeting the requirements of the mud weight window.

10. The method of drilling a well into strata of claim 9, wherein the transform comprises a function to transform a continuous-time signal into different scale components all assigned with a frequency range.

11. The method of drilling a well into strata of claim 9, wherein the artificial intelligence model comprises a deep neural network.

12. The method of drilling a well into strata of drilling a well into strata of claim 9, further comprising the steps of:
(a) receiving offset data from at least one offset well; and
(b) applying the offset data to the neural network.

13. The method of drilling a well into strata of claim 12, wherein the offset data includes offset data selected from a list consisting of: well logs; mud logs; daily drilling and geology reports; end of well reports; and combinations thereof.

14. The method of drilling a well into strata of claim 13, wherein the well logs data include well logs data selected from a list consisting of: gamma ray data; sonic data; density data; resistivity data; neutron porosity data; image data; and combinations thereof.

15. The method of drilling a well into strata of claim 9, wherein the geomechanical model components include geomechanical model components selected from a list consisting of: pore pressure; in-situ stresses; collapse gradient; fracture gradient and combinations thereof.

16. A drilling system, comprising:
(a) a vibration sensor affixed to a drill bit unit;
(b) a computer that is responsive to the vibration sensor so as to receive bit vibration data from the vibration sensor, the computer programmed to:
(i) receive electronic drilling recorder data regarding drilling of the wellbore;
(ii) apply a function to transform a continuous-time signal into different scale components all assigned with a frequency range to the electronic drilling recorder data and to the bit vibration data so as to generate filterable data;
(iii) filter at least one undesirable component from the filterable data, so as to generate clean data; and
(iv) apply the clean data to a neural network trained to associate data with a plurality of geomechanical model components, so as to generate a geomechanical model corresponding to the electronic drilling recorder data and the bit vibration data.

17. The drilling system of claim 16, wherein the computer is further programmed to generate a mud weight window based on the geomechanical model.

18. The drilling system of claim 17, further comprising a mud mixing device configured to mix a drilling mud that conforms to the mud weight window.

19. The drilling system of claim 16, wherein the computer is further programmed to:
(a) receive offset data from at least one offset well, the offset data including offset data selected from a list consisting of: well logs; mud logs; daily drilling and geology reports; end of well reports; and combinations thereof; and
(b) apply the offset data to the neural network.

20. The drilling system of claim 16, wherein the geomechanical model components include geomechanical model components selected from a list consisting of: pore pressure; in-situ stresses; collapse gradient; fracture gradient and combinations thereof.
